(19) United States
(12) Patent Application Publication
(10) Pub. No.: US 2009/0159212 A1
(43) Pub. Date: Jun. 25, 2009

(54) JET PLASMA GUN AND PLASMA DEVICE USING THE SAME

(75) Inventors: Chia-Chiang Chang, Taipei County (TW); Chen-Der Tsai, Hsinchu County (TW); Wen-Tung Hsu, Hsinchu County (TW); Chih-Wei Chen, Taipei County (TW); Chin-Jyi Wu, Hsinchu County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: INDUSTRIAL TECHNOLOGY RESEARCH INSTITUTE, Hsinchu (TW)

(21) Appl. No.: 12/136,838

(22) Filed: Jun. 11, 2008

(30) Foreign Application Priority Data
Dec. 25, 2007 (TW) 96150036

(51) Int. Cl. C23F 1/02; C23C 16/44; C23C 14/34

(52) U.S. Cl. 156/345.33; 118/723 R; 204/298.07

(57) ABSTRACT

A jet plasma gun and a plasma device using the same are provided. The jet plasma gun is for jetting plasma to process a surface of a substrate. The jet plasma gun includes a plasma producer, a plasma nozzle and a barrier. The plasma producer is for providing plasma. The plasma nozzle disposed between the substrate and plasma producer has a first opening and a second opening. The first opening faces plasma producer, and the second opening faces the substrate. The barrier being an insulator is disposed between the plasma nozzle and the substrate and has a through hole corresponding to the second opening. The plasma passes through the plasma nozzle and the through hole to reach the substrate.

This application claims the benefit of Taiwan application Serial No. 96150036, filed Dec. 25, 2007, the subject matter of which is incorporated herein by reference.

### BACKGROUND OF THE INVENTION

1. Field of the Invention

The invention relates in general to a plasma gun and a plasma device using the same, and more particularly to a jet plasma gun having a plasma nozzle and a plasma device using the same.

2. Description of the Related Art

As the semiconductor industry is experiencing rapid growth, various methods and devices for manufacturing process are provided and used. The plasma can be used for surface cleaning, surface etching, trench etching, thin-film deposition and surface component change on the surface of a substrate. Examples of the plasma device include the plasma cleaning device, plasma enhance chemical vapor deposition (PECVD) device, plasma enhance reactive ion etching (PERIE) device, micro-wave plasma oxidation device, micro-wave plasma nitridation device, ionized metal plasma (IMP) deposition device and sputtering deposition device. The jet plasma gun is mostly used in the above-mentioned plasma devices and requires an environment to jet the plasma at a high speed.

Although the plasma is in the state of electric neutrality, the atmosphere of the plasma includes particles with different electrical potentials. Examples of the particles include atoms, radical base, ions, molecules, molecular radical base, polar molecules, electrons and photons. During the course of processing the surface of the substrate, the plasma is likely to gather particles of the same electric property on the surface of the substrate. For example, when most of the electrons are close to the surface of the substrate, particles carrying negative electricity will be attracted to move towards the substrate, and particle carrying positive electricity will be attracted to move in an opposite direction and gather at the plasma gun. Therefore, a bias voltage is formed between the plasma gun and the surface of the substrate. If the distance between the substrate and the plasma gun is very small and the plasma gun provides high-voltage plasma (for example, during the surface treatment by plasma under an atmospheric environment), mean free path of the particles of the plasma is so small that unexpected collision occurs between particles, resulting in unexpected and uncontrollable abnormal electrical discharge between the plasma gun and the surface of the substrate. For example, electric arc and hairspring discharge will damage the substrate surface and the plasma device.

In addition, during the process of generating plasma, electric arc will occur at the opening of the jet plasma gun due to the cyclone in the atmosphere of the plasma. The electric arc will damage the jet plasma gun and make metal particles coming off the surface of the plasma nozzle and polluting the substrate. Because the electric arc and abnormal electrical discharge occur at the opening of the jet plasma gun, the adaptability of plasma in substrate treatment is restricted.

### SUMMARY OF THE INVENTION

The invention is directed to a jet plasma gun and a plasma device using the same. By way of using an insulating material, the electric arc and abnormal electrical discharge of the plasma are suppressed, and the quality of surface treatment on the substrate is improved.

According to a first aspect of the present invention, a jet plasma gun for jetting plasma to process a surface of a substrate is provided. The jet plasma gun includes a plasma producer, a plasma nozzle and a barrier. The plasma producer is for providing plasma. The plasma nozzle disposed between the substrate and plasma producer has a first opening and a second opening, wherein the first opening faces plasma producer, and the second opening faces the substrate. The barrier being an insulator disposed between the plasma nozzle and the substrate has a through hole corresponding to the second opening. The plasma passes through the plasma nozzle and the through hole to reach the substrate.

According to a second aspect of the present invention, a plasma device for providing plasma to process a surface of a substrate is provided. The plasma device includes a base, a jet plasma gun and a cavity. The jet plasma gun includes a plasma producer and a plasma nozzle. The substrate is placed on a bearing surface of the base. The plasma producer is for providing plasma. The plasma nozzle disposed between the substrate and plasma producer has a first opening and a second opening, wherein the first opening faces plasma producer, and the second opening faces the base. The cavity is for receiving the base and the plasma nozzle, wherein the jet plasma gun is fixed in cavity, and the bearing surface of the base is electrically isolated from the cavity.

The invention will become apparent from the following detailed description of the preferred but non-limiting embodiments. The following description is made with reference to the accompanying drawings.

### BRIEF DESCRIPTION OF THE DRAWINGS

FIG. 1A shows a plasma device according to a first embodiment of the invention;

FIG. 1B is a partial cross-sectional view of a plasma nozzle in FIG. 1A;

FIG. 2A shows a jet plasma gun and a substrate according to a second embodiment of the invention;

FIG. 2B is a perspective view of a barrier of the jet plasma gun in FIG. 2A;

FIG. 3 is a cross-sectional view of another plasma nozzle and the barrier according to another embodiment of the invention; and

FIG. 4 is a cross-sectional view of yet another plasma nozzle and the barrier according to yet another embodiment of the invention.

### DETAILED DESCRIPTION OF THE INVENTION

### First Embodiment

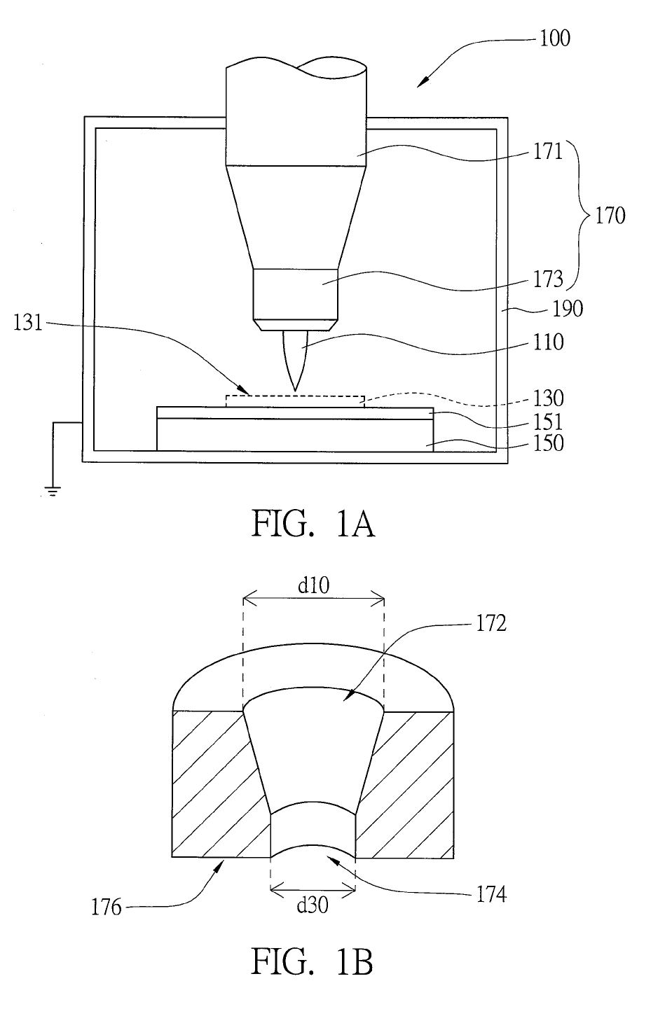

Referring to FIG. 1A and FIG. 1B, FIG. 1A shows a plasma device according to a first embodiment of the invention, and FIG. 1B is a partial cross-sectional view of a plasma nozzle in FIG. 1A. The plasma device 100 is for providing a plasma 110 to process a surface of a substrate 130. The plasma device 100 includes a base 150, a jet plasma gun 170 and a cavity 190. The jet plasma gun 170 includes a plasma producer 171 and a plasma nozzle 173. The substrate 130 is placed on a bearing surface of the base 150. The plasma producer 171 is for providing a plasma 110. The plasma nozzle 173 is disposed between the substrate 130 and plasma producer 171 and has a first opening 172 and a second opening 174. The first opening 172 faces plasma producer 171, and the second opening 174 faces the base 150. The cavity 190 is for receiving the base 150 and the plasma nozzle 173. The jet plasma gun 170 is fixed in cavity 190, and the bearing surface of the base 150 is electrically isolated from the cavity 190.

As indicated in FIG. 1A, the base 150 includes an insulating layer 151 whose top surface is used as a bearing surface of the base 150. That is, the insulating layer 151 enables the bearing surface of the base 150 to be electrically isolated from the grounded cavity 190, so that the substrate 130 shows a state of floating potential in the atmosphere of the plasma 110. In a greater detail, the substrate 130 is electrically isolated from the cavity 190 via the insulating layer 151. When the electrons in the atmosphere of the plasma 110 contact a surface 131 of the substrate 130 and react with the neutral substrate 130, the substrate 130 carries negative electricity and attracts particles of the plasma 130 carrying positive electricity to the substrate 130 to react with the surface 131 and make the substrate 130 restore electric neutrality.

Besides, a minimum diameter d10 of the first opening 172 is substantially larger than a maximum diameter d30 of the second opening 174. The plasma 110 is jetted to the surface 131 of the substrate 130 from the plasma nozzle 173 through the first opening 172 and the second opening 174, wherein the cross-section is gradually narrowed from the first opening 172 to the second opening 174.

Furthermore, the plasma device 100 produces plasma 110 under an atmospheric environment. The plasma 110 is used for removing a particular particle of the surface 131 of the substrate 130. The plasma device 100 can be a plasma cleaning device. The plasma 110 can also be used for removing a surface layer of the substrate 130. The plasma device 100 can be a plasma enhance reactive ion etching (PERIE) device. In addition, the plasma 110 can also be used for forming a deposition layer on the substrate 130. The plasma device can be a plasma enhance chemical vapor deposition (PECVD) device, an ionized metal plasma deposition (IMP) device or a sputter. Besides, the plasma device 100, which can be used in a continuous processing device, further includes a conveyor (not illustrated). The base 150 is disposed on the conveyor for conveying the substrate 130.

In the first embodiment of the invention, the plasma device is electrically isolated from the cavity by placing a bearing surface of the substrate, so that the substrate shows a state of floating potential during plasma processing, suppressing the particle of the plasma being polarized and preventing the plasma from generating unexpected bias voltage. In the present embodiment of the invention, electric arc or hairspring discharge will not occur between the jet plasma gun and the substrate.

### Second Embodiment

The jet plasma gun of the second embodiment of the invention includes a barrier. As for other similarities between the first embodiment and the second embodiment, the same designations are used and are not repeated here.

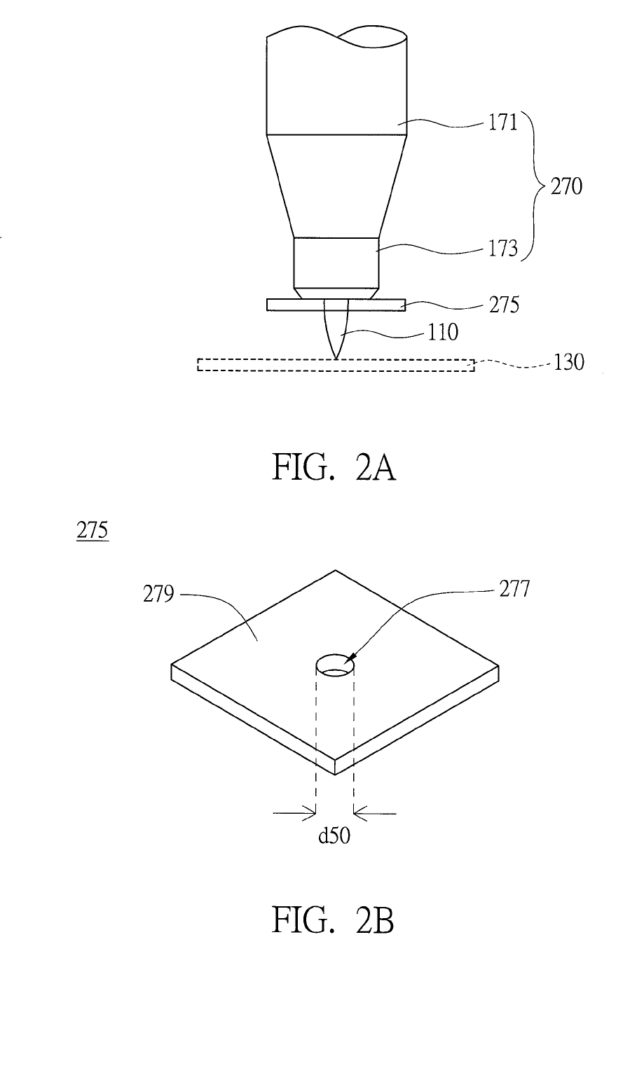

Referring to FIGS. 2A and 2B, FIG. 2A shows a jet plasma gun and a substrate according to a second embodiment of the invention, and FIG. 2B is a perspective view of a barrier of the jet plasma gun in FIG. 2A. The jet plasma gun 270 includes a plasma producer 171, a plasma nozzle 173 and a barrier 275. The barrier 275 being an insulator is disposed between plasma nozzle 173 and the substrate 130 and has a through hole 277 corresponding to the second opening 174 (illustrated in FIG. 1B. The plasma 110 passes through the plasma nozzle 173 and the through hole 277 to reach the substrate 130.

As indicated in FIGS. 1B and 2B, the barrier 275 is coupled to the plasma nozzle 173. The second opening 174 of the plasma nozzle 173 is disposed on a surface 176 of the plasma nozzle 173. A surface 279 of the barrier 275 faces the surface 176 of the nozzle 173, and the area of the surface 279 of the barrier 275 at least is substantially equal to that of the surface 176. A maximum diameter d50 of the through hole 277 at most is substantially equal to a minimum diameter d30 of the second opening 174.

When the plasma 110 reaches the second opening 174 of the plasma nozzle 173, the surface 279 of the insulated barrier 275 suppresses the plasma 110 from generating electric arc at the opening of the plasma nozzle 173. Therefore, the barrier 275 effectively avoids the plasma 110 hitting the plasma jet gun 270 and making the metal particles come off and fall on the substrate 130. Besides, the barrier 275 needs to possess higher chemical stability and bear higher temperature so that the barrier 275 can remain stability when the plasma 110 is processing the surface of the substrate 130. Preferably, the barrier 275 is a quartz glass or a ceramic material.

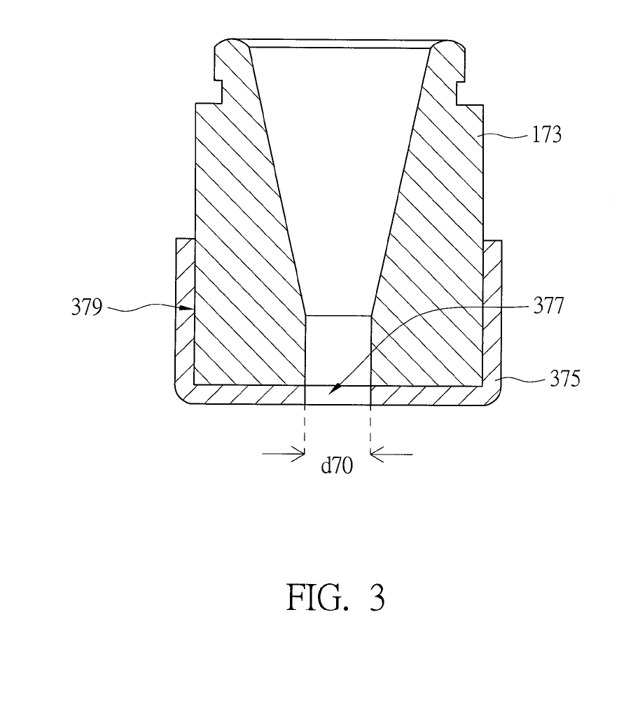

Besides, the barrier of the jet plasma gun has many different modes. Referring to FIG. 3, a cross-sectional view of another plasma nozzle and the barrier according to another embodiment of the invention is shown. The barrier 375 has a through hole 377. A diameter d70 of the through hole 377 at least is substantially equal to a diameter d30 of the second opening 174. A surface 379 of the barrier 375 further envelops the plasma nozzle 173. Preferably, the barrier 375 is engaged with the plasma nozzle 173 by way of rotation.

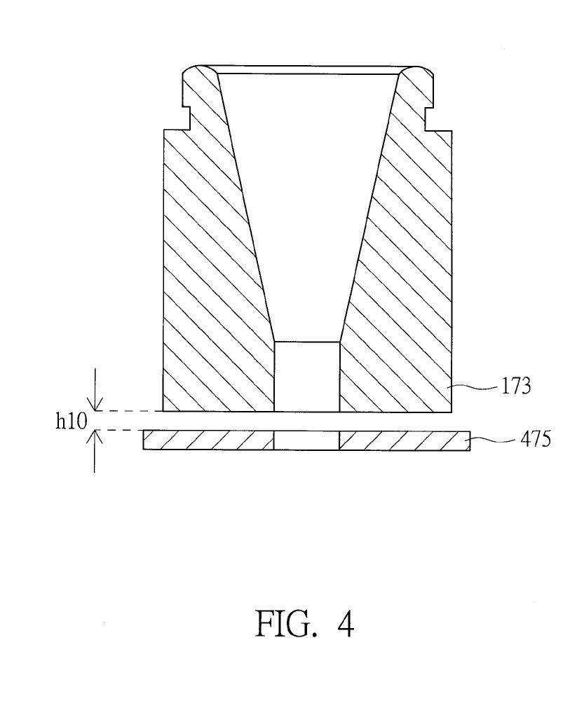

Referring to FIG. 4, a cross-sectional view of yet another plasma nozzle and the barrier according to yet another embodiment of the invention is shown. There is a distance h10 between the barrier 475 and the plasma nozzle 173. According to the modes of the plasma device, when the distance h10 exists between the barrier 475 and the plasma nozzle 173, the barrier 475 can be accompanied by a collimator, and the plasma nozzle 173 can be shifted with respect to the barrier 475. Or, the plasma nozzle 173 and the barrier 475 can be shifted with respect to the substrate 130. Thus, the plasma device has a wide range of application.

The jet plasma gun of the second embodiment of the invention includes a barrier disposed between the plasma nozzle and the substrate, so that when the plasma reaches the second opening of plasma nozzle, the plasma will not hit the jet plasma gun when cyclone phenomenon occurs. After the plasma passes through the through hole of the barrier, the air current and electric state of the plasma are more stable, so that the quality of the surface treatment of the substrate is improved.

According to the jet plasma gun and the plasma device using the same disclosed in the above embodiments of the invention, the substrate is placed on the bearing surface of a carrier electrically isolated from the cavity, and there is a barrier disposed between the plasma nozzle and the substrate. After the plasma, which is electrically isolated from the carrier, exits the opening of the plasma nozzle, the plasma will not generate abnormal electrical discharge between the jet plasma gun and the substrate, so that the plasma can stably process the surface of the substrate. The disposition of the barrier between the plasma nozzle and the substrate suppresses the plasma generating electric arc outside the plasma nozzle and avoids the particles coming off the surface of the plasma nozzle and polluting the substrate. Therefore, during the surface treatment of the substrate, the jet plasma gun and the plasma device using the same of the invention control the plasma to be at a more stable state, hence improving the quality of surface treatment of the substrate and making the application range of the plasma device wider.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A jet plasma gun for jetting plasma to process a surface of a substrate, the jet plasma gun comprising:
a plasma producer for providing the plasma;
a plasma nozzle disposed between the substrate and the plasma producer, wherein the plasma nozzle has a first opening and a second opening, the first opening faces the plasma producer, and the second opening faces the substrate; and
a barrier being an insulator disposed between the plasma nozzle and the substrate, wherein the barrier has a through hole corresponding to the second opening, and the plasma passes through the plasma nozzle and the through hole to reach the substrate.

2. The jet plasma gun according to claim 1, wherein the second opening is disposed on a first surface of the plasma nozzle, a second surface of the barrier faces the first surface, and an area of the second surface is at least equal to an area of the first surface.

3. The jet plasma gun according to claim 1, wherein a maximum diameter of the through hole at most is substantially equal to a minimum diameter of the second opening.

4. The jet plasma gun according to claim 1, wherein the barrier is coupled to the plasma nozzle, envelops the plasma nozzle or keeps a distance from the plasma nozzle.

5. The jet plasma gun according to claim 1, wherein the plasma is for removing a particular particle of the surface of the substrate, for removing a surface layer of the substrate, or for forming a deposition layer on the substrate.

6. The jet plasma gun according to claim 1, wherein the barrier is made by ceramic material or quartz glass.

7. A plasma device for providing a plasma to process a surface of a substrate, the plasma device comprising:
a base, wherein the substrate is placed on a bearing surface of the base;
a jet plasma gun, comprising:
a plasma producer for providing the plasma; and
a plasma nozzle disposed between the substrate and the plasma producer, wherein the plasma nozzle has a first opening and a second opening, the first opening faces the plasma producer, and the second opening faces the base; and
a cavity for receiving the base and the plasma nozzle, wherein the jet plasma gun is fixed in the cavity, and the bearing surface of the base is electrically isolated from the cavity.

8. The plasma device according to claim 7, wherein the base comprises an insulating layer whose one surface is used as the bearing surface.

9. The plasma device according to claim 7, wherein the jet plasma gun further comprises:
a barrier being an insulator disposed between the plasma nozzle and the substrate, wherein the barrier has a through hole corresponding to the second opening, and the plasma passes through the plasma nozzle and the through hole to reach the substrate.

10. The plasma device according to claim 7, wherein the device generates the plasma under an atmospheric environment.

11. The plasma device according to claim 7, wherein the second opening is disposed on a first surface of the plasma nozzle, a second surface of the barrier faces the first surface, and an area of the second surface is at least equal to an area of the first surface.

12. The plasma device according to claim 7, wherein a maximum diameter of the through hole at most is substantially equal to a minimum diameter of the second opening.

13. The plasma device according to claim 9, wherein the barrier is coupled to the plasma nozzle, envelops the plasma nozzle or keeps a distance from the plasma nozzle.

14. The plasma device according to claim 7, wherein the plasma is for removing a particular particle of the surface of the substrate, for removing a surface layer of the substrate, or for forming a deposition layer on the substrate.

15. The plasma device according to claim 9, wherein the barrier is made by ceramic material or quartz glass.
